(19) United States
(12) Patent Application Publication
(10) Pub. No.: US 2014/0329382 A1
(43) Pub. Date: Nov. 6, 2014

(54) METHOD OF FABRICATING SEMICONDUCTOR DEVICE HAVING BUMP

(71) Applicant: Samsung Electronics Co., Ltd., Suwon-si (KR)

(72) Inventors: SON-KWAN HWANG, Suwon-si (KR); JIN-HO CHUN, Seoul (KR); BYUNG-LYUL PARK, Seoul (KR); JEONG-GI JIN, Osan-si (KR); GIL-HEYUN CHOI, Seoul (KR)

(73) Assignee: Samsung Electronics Co., Ltd., Suwon-si (KR)

(21) Appl. No.: 14/080,755

(22) Filed: Nov. 14, 2013

(30) Foreign Application Priority Data
May 2, 2013 (KR) 10-2013-0049494

(51) Int. Cl. H01L 23/00

(52) U.S. Cl. CPC H01L 24/11
USPC 438/614

(57) ABSTRACT

Provided is a method of fabricating a semiconductor device. The method includes forming a photoresist pattern having a side recess on a seed metal layer and forming a plating layer having a hem using a plating process to fill the side recess.

### CROSS-REFERENCE TO RELATED APPLICATION

This application claims priority under 35 U.S.C. §119 to Korean Patent Application No. 10-2013-0049494 filed on May 2, 2013, the disclosure of which is hereby incorporated by reference in its entirety.

### BACKGROUND

1. Field

Embodiments of the disclosed subject matter provide a semiconductor device having bumps and a method of fabricating the same.

2. Description of Related Art

As the integration density of high performance semiconductor devices as gradually increased, the number of bumps required for input/output (I/O) operations has also increased. Thus, the pitches of the bumps have shrunk, and the demand for the mechanical and physical stability of the bumps has increased. In particular, undercuts may be formed in lower portions of the bumps during the formation of the bumps. Since the undercuts adversely affect the mechanical and physical stability of the bumps, research into a technique of reducing the undercuts or reducing the influence of the undercuts on the bumps is needed.

### SUMMARY

Embodiments of the disclosed subject matter provide a semiconductor device having bumps.

Other embodiments of the disclosed subject matter provide a method of fabricating a semiconductor device having bumps.

Other embodiments of the disclosed subject matter provide a bump of a semiconductor device, upon which the influence of an undercut may be reduced.

Other embodiments of the disclosed subject matter provide a method of forming a bump of a semiconductor device, upon which the influence of an undercut may be reduced.

Other embodiments of the disclosed subject matter provide a bump of a semiconductor device, which includes a hem.

Other embodiments of the disclosed subject matter provide a method of forming a bump of a semiconductor device, which includes a hem.

The technical objectives of the disclosed subject matter are not limited to the above disclosure; other objectives may become apparent to those of ordinary skill in the art based on the following descriptions.

In accordance with an aspect of the disclosed subject matter, a method of fabricating a semiconductor device includes forming a metal line on a substrate, forming a passivation layer having an opening on the metal line to expose a portion of a top surface of the metal line, conformally forming a seed metal layer on the exposed top surface of the metal line and the passivation layer, forming a photoresist layer containing a base resin, a cross-linking agent, and a solvent on the seed metal layer, removing the solvent from the photoresist layer using a pre-exposure bake process to leave part of the solvent in the photoresist layer, performing an exposure process, a post-exposure bake process, and a developing process to form a photoresist pattern having a bump hole exposing a first portion of the seed metal layer, the bump hole having a side recess formed by removing the photoresist pattern outward from a side surface of the bump hole in a longitudinal sectional view, forming a first plating layer using a first plating process on the first portion of the seed metal layer to fill the bump hole, the first plating layer having a hem filling the side recess, removing the photoresist pattern to expose a second portion of the seed metal layer, and removing the exposed second portion of the seed metal layer. Herein, an undercut is formed under the hem by removing the seed metal layer.

In accordance with another aspect of the disclosed subject matter, a method of fabricating a semiconductor device includes forming a passivation layer on a substrate, forming a barrier metal layer on the passivation layer, forming a seed metal layer on the barrier metal layer, forming a photoresist layer containing an organic solvent on the seed metal layer, performing a pre-exposure bake process to remove a large portion of the organic solvent from the photoresist layer, converting the photoresist layer into a photoresist pattern using an exposure process, a post-exposure process, and a developing process, the photoresist pattern having a bump hole having a substantially vertical sidewall to expose a portion of a top surface of the seed metal layer, and forming a plating layer using a plating process on the exposed top surface of the seed metal layer to fill the bump hole. The bump hole has a side recess partially exposing the top surface of the seed metal layer in a lower portion of the photoresist pattern. The plating layer includes a protruding hem to fill the side recess.

Specific particulars of other embodiments are included in detailed descriptions and drawings.

### BRIEF DESCRIPTION OF THE DRAWINGS

The foregoing and other features and advantages of the disclosed subject matter will be apparent from the more particular description of preferred embodiments of the disclosed subject matter, as illustrated in the accompanying drawings in which like reference characters refer to the same parts throughout the different views. The drawings are not necessarily to scale, emphasis instead being placed upon illustrating the principles of the disclosed subject matter. In the drawings:

FIGS. 1A, 1B, 1C, and 1D are schematic longitudinal sectional views of semiconductor devices according to embodiments of the disclosed subject matter;

FIGS. 2A, 2B, 2C, 2D, 2E, 2F, 2G, 2H, 2I, 2J, 2K, and 2L are schematic longitudinal sectional views illustrating techniques of manufacturing semiconductor devices according to embodiments of the disclosed subject matter;

FIG. 3 is another schematic longitudinal sectional view illustrating a technique of manufacturing semiconductor devices according to an embodiment of the disclosed subject matter;

FIG. 4A is a conceptual diagram of a memory module including at least one of semiconductor devices having bumps according to various embodiments of the disclosed subject matter;

FIG. 4B is a conceptual diagram of a memory card including at least one of semiconductor devices having bumps according to various embodiments of the disclosed subject matter;

FIGS. 4C and 4D are conceptual block diagrams of electronic systems including at least one of semiconductor devices having bumps according to various embodiments of the disclosed subject matter; and

FIG. 4E is a schematic diagram of a wireless mobile device including at least one of semiconductor devices having bumps according to various embodiments of the disclosed subject matter.

FIG. 5 is a flow chart illustrating a technique of manufacturing semiconductor devices according to an embodiment of the disclosed subject matter;

### DETAILED DESCRIPTION OF THE EMBODIMENTS

Various embodiments will now be described more fully with reference to the accompanying drawings in which some embodiments are shown. This disclosed subject matter may, however, be embodied in different forms and should not be construed as limited to the embodiments set forth herein. Rather, these embodiments are provided so that this disclosure is thorough and complete and fully conveys the scope of the disclosed subject matter to those skilled in the art.

The terminology used herein is for the purpose of describing particular embodiments only and is not intended to be limiting of the disclosed subject matter. As used herein, the singular forms “a”, “an” and “the” are intended to include the plural forms as well, unless the context clearly indicates otherwise. It will be further understood that the terms “comprises” and/or “comprising,”, when used herein, specify the presence of stated features, integers, steps, operations, elements, and/or components, but do not preclude the presence or addition of one or more other features, integers, steps, operations, elements, components, and/or groups thereof.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items.

Spatially relative terms, such as “below”, “beneath”, “lower”, “above”, and “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments of the disclosed subject matter are described herein with reference to cross-section and/or plan illustrations that are schematic illustrations of idealized embodiments of the disclosed subject matter. In the drawings, the thicknesses of layers and regions are exaggerated for clarity. As such, variations from the shapes of the illustrations as a result, for example, of manufacturing techniques and/or tolerances, are to be expected. Thus, embodiments of the disclosed subject matter should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the disclosed subject matter.

Like numbers refer to like elements throughout. Thus, the same or similar numbers may be described with reference to other drawings even if they are neither mentioned nor described in the corresponding drawing. Also, even elements that are not denoted by reference numbers may be described with reference to other drawings.

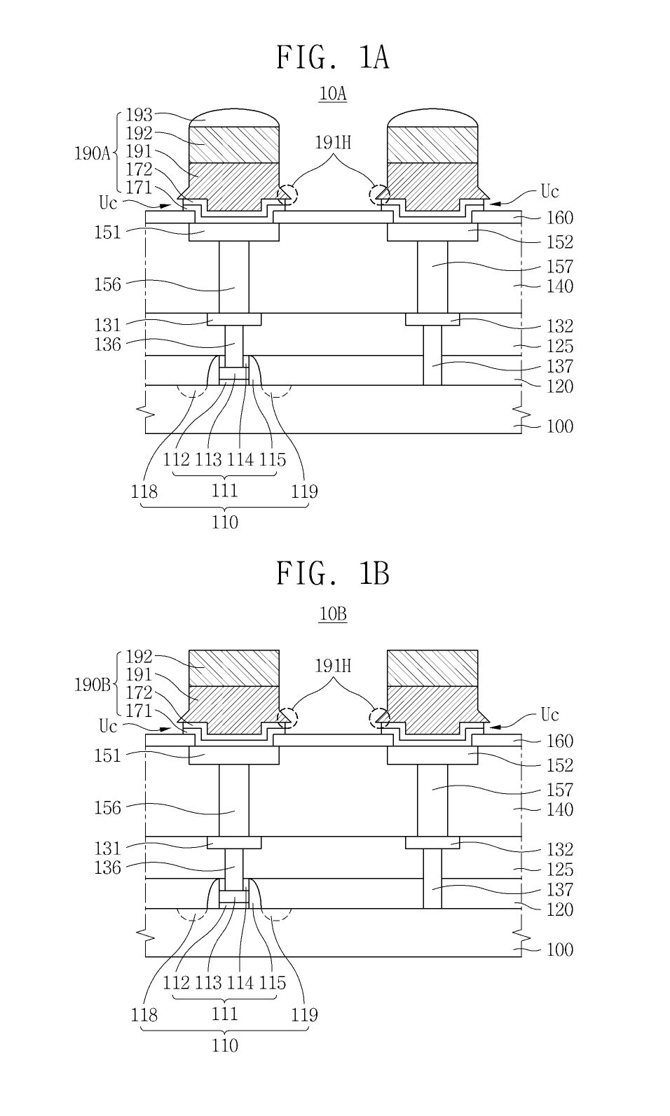

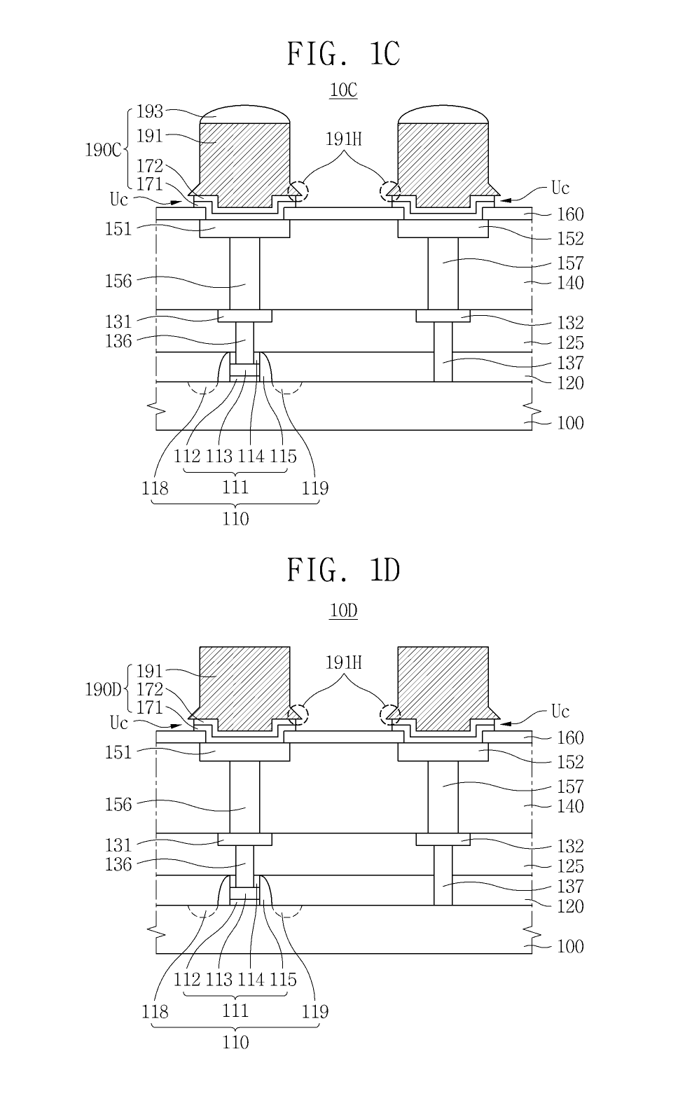

FIGS. 1A through 1D are schematic longitudinal sectional views of semiconductor devices according to embodiments of the disclosed subject matter.

Referring to FIG. 1A, a semiconductor device 10A according to embodiments of the disclosed subject matter may include a transistor 110, a lower interlayer insulating layer 120, an upper interlayer insulating layer 125, lower metal lines 131 and 132 and lower vias 136 and 137, an inter-metal insulating layer 140, upper metal lines 151 and 152 and upper vias 156 and 157, a passivation layer 160, and bumps 190A, which may be disposed on a substrate 100.

The substrate 100 may include a single crystalline silicon wafer, a silicon-on-insulator (SOI0 wafer, a silicon germanium (SiGe) wafer, a silicon carbide (SiC) wafer, or a compound semiconductor wafer in which Group III elements (e.g., aluminum (Al), gallium (Ga), and indium (In)) combine with Group V elements (e.g., oxygen (O), arsenic (As), and antimony (Sb)).

The transistor 110 may include a gate pattern 111, a source region 118, and a drain region 119. The gate pattern 111 may include a gate insulating layer 112, a gate electrode 113, a gate capping layer 114, and gate spacers 115. The gate insulating layer 112 may be directly formed on a surface of the substrate 100. The gate insulating layer 112 may include oxide. For example, the gate insulating layer 112 may include oxidized silicon (SiO₂) or an oxidized metal, such as HfO₂ or Al₂O₃. The gate electrode 113 may include doped polycrystalline silicon (doped poly-Si), a metal silicide, and/or a metal, such as tungsten (W) or copper (Cu). The gate capping layer 114 and the gate spacers 115 may include an insulating material, such as silicon nitride, silicon oxide, or silicon oxynitride. The source region 118 and the drain region 119 may be portions of the substrate 100 and include an n-type dopant, such as phosphorous (P) or arsenic (As), or a p-type dopant, such as boron (B).

The lower interlayer insulating layer 120 may cover the substrate 100 and the transistor 110. For example, the lower interlayer insulating layer 120 may be in contact with the surface of the substrate 100 and the gate spacers 115 of the transistor 110. Top surfaces of the lower interlayer insulating layer 120 and the transistor 110 may be co-planar. The lower interlayer insulating layer 120 may include silicon oxide.

The upper interlayer insulating layer 125 may cover the lower interlayer insulating layer 120 and the transistor 110. The upper interlayer insulating layer 125 may include silicon oxide or silicon nitride.

The lower metal lines 131 and 132 may be buried, at least partially, in an upper portion of the upper interlayer insulating layer 125. For example, top surfaces of the lower metal lines 131 and 132 and a top surface of the upper interlayer insulating layer 125 may be co-planar. The lower metal lines 131 and 132 may include a first lower metal line 131 electrically connected to the gate electrode 113 and a second lower metal line 132 electrically connected to the substrate 100. The lower metal lines 131 and 132 may include a metal, such as tungsten or copper.

The first lower metal line 131 may be electrically connected to the gate electrode 113 through the first lower via 136. For example, the first lower via 136 may vertically penetrate the upper interlayer insulating layer 125 and the gate capping layer 114. The second lower metal line 132 may be electrically connected to the substrate 100 through the second lower via 137. For instance, the second lower via 137 may vertically penetrate the upper interlayer insulating layer 125 and the lower interlayer insulating layer 120. The first lower via 136 and the second lower via 137 may include a metal, such as tungsten or copper.

The inter-metal insulating layer 140 may cover the upper interlayer insulating layer 125 and the lower metal lines 131 and 132. The inter-metal insulating layer 140 may include silicon oxide.

The upper metal lines 151 and 152 may be buried in an upper portion of the inter-metal insulating layer 140. For example, top surfaces of the upper metal lines 151 and 152 and a top surface of the inter-metal insulating layer 140 may be co-planar. The upper metal lines 151 and 152 may include a first upper metal line 151 electrically connected to the first lower metal line 131 and a second upper metal line 152 electrically connected to the second lower metal line 132. The upper metal lines 151 and 152 may include a metal, such as tungsten or copper.

The first upper metal line 151 may be electrically connected to the first lower metal line 131 through the first upper via 156, while the second upper metal line 152 may be electrically connected to the second lower metal line 132 through the second upper via 157. For example, the first upper via 156 and the second upper via 167 may vertically penetrate the inter-metal insulating layer 140. The first upper via 156 and the second upper via 167 may include a metal, such as tungsten or copper.

The passivation layer 160 may cover the inter-metal insulating layer 140 and the upper metal lines 151 and 152. The passivation layer 160 may at least partially expose the top surfaces of the upper metal lines 151 and 152. The passivation layer 160 may include silicon nitride or polyimide. It is understood that the above are merely a few illustrative examples to which the disclosed subject matter is not limited.

Each of the bumps 190A may include a barrier metal layer 171, a seed metal layer 172, a lower plating layer 191 having hems 191H, an upper plating layer 192, and a solder layer 193.

The barrier metal layer 171 may cover the exposed top surfaces of the upper metal lines 151 and 152 and extend on a top surface of the passivation layer 160. The barrier metal layer 171 may include a barrier metal, such as titanium (Ti), titanium nitride (TiN), tantalum (Ta), or tantalum nitride (TaN).

The seed metal layer 172 may be directly formed on the barrier metal layer 171. The seed metal layer 172 may include copper. The barrier metal layer 171 and the seed metal layer 172 may be conformally formed. Side end portions of the barrier metal layer 171 and side end portions of the seed metal layer 171 may be substantially vertically aligned. The seed metal layer 172 may include a seed metal, such as copper (Cu), ruthenium (Ru), nickel (Ni), and tungsten (W).

The lower plating layer 191 may be formed on the seed metal layer 172. The lower plating layer 191 may have hems 191H, which may protrude more than the side end portions of the barrier metal layer 171 or the seed metal layer 172 in a lateral direction. From a side view, each of the hems 191H may have a foot shape having an inclined top surface and a horizontal bottom surface. From a top view, each of the hems 191H may have a rim shape to surround the periphery of the barrier metal layer 171, and/or the seed metal layer 172 of the bumps 190A. Accordingly, an undercut Uc may be formed under each of the hems 191H. The lower plating layer 191 may include nickel or copper.

The upper plating layer 192 may be formed on the lower plating layer 191. The upper plating layer 192 may include copper or nickel, etc. Each of the lower plating layer 191 and the upper plating layer 192 may have a mesa shape.

The solder layer 193 may have a convex shape on the upper plating layer 192. The solder layer 193 may include tin (Sn) and silver (Ag), etc.

Referring to FIG. 1B, a semiconductor device 10B according to embodiments of the disclosed subject matter may include a transistor 110, a lower interlayer insulating layer 120, an upper interlayer insulating layer 125, lower metal lines 131 and 132 and lower vias 136 and 137, an inter-metal insulating layer 140, upper metal lines 151 and 152 and upper vias 156 and 157, a passivation layer 160, and bumps 190B, which may be disposed on a substrate 100. Each of the bumps 190B may include a barrier metal layer 171, a seed metal layer 172, a lower plating layer 191 having hems 191H, and an upper plating layer 192. A top surface of the upper plating layer 192 may be exposed. The semiconductor device 10B according to the current embodiments of the disclosed subject matter may include the bumps 190B having the upper plating layer 192 with the exposed top surface.

The bumps 190B having the upper plating layer 192 with the exposed top surface may be applied to a bump-to-bump direct bonding technique. For example, when the upper plating layer 192 contains copper, the bumps 190B may be applied to a copper bump direct bonding technique.

Referring to FIG. 1C, a semiconductor device 10C according to embodiments of the disclosed subject matter may include a transistor 110, a lower interlayer insulating layer 120, an upper interlayer insulating layer 125, lower metal lines 131 and 132 and lower vias 136 and 137, an inter-metal insulating layer 140, upper metal lines 151 and 152 and upper vias 156 and 157, a passivation layer 160, and bumps 190C, which may be disposed on a substrate 100. Each of the bumps 190C may include a barrier metal layer 171, a seed metal layer 172, a lower plating layer 191 having hems 191H, and a solder layer 193. The lower plating layer 191 may include nickel or copper.

Referring to FIG. 1D, a semiconductor device 10D according to embodiments of the disclosed subject matter may include a transistor 110, a lower interlayer insulating layer 120, an upper interlayer insulating layer 125, lower metal lines 131 and 132 and lower vias 136 and 137, an inter-metal insulating layer 140, upper metal lines 151 and 152 and upper vias 156 and 157, a passivation layer 160, and bumps 190D, which may be disposed on a substrate 100. Each of the bumps 190D may include a barrier metal layer 171, a seed metal layer 172, and a lower plating layer 191 having hems 191H. The lower plating layer 191 may include copper.

The semiconductor devices 10A to 10D according to various embodiments of the disclosed subject matter may respectively include the bumps 190A to 190D having the hems 191H. The hem 191H may reduce a horizontal width or depth of the undercut Uc of the barrier metal layer 171 and the seed metal layer 172 disposed under the bumps 190A to 190D. Accordingly, since the influence of the undercut Uc upon the bumps 190A to 190D of the semiconductor devices 10A to 10D is reduced, architectural characteristics of the bumps 190A to 190D may be improved so that horizontal areas occupied by the bumps 190A to 190D. Also, a distance between the bumps 190A to 190D may shrink. Therefore, the semiconductor devices 10A to 10D according to the embodiments of the disclosed subject matter may have a larger number of bumps 190A to 190D arranged within a smaller area.

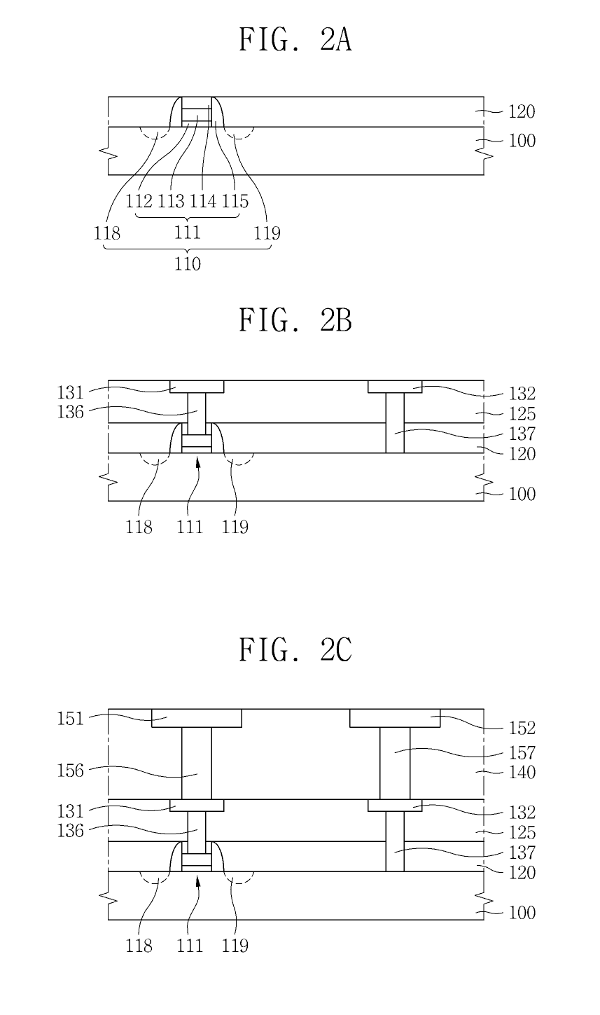

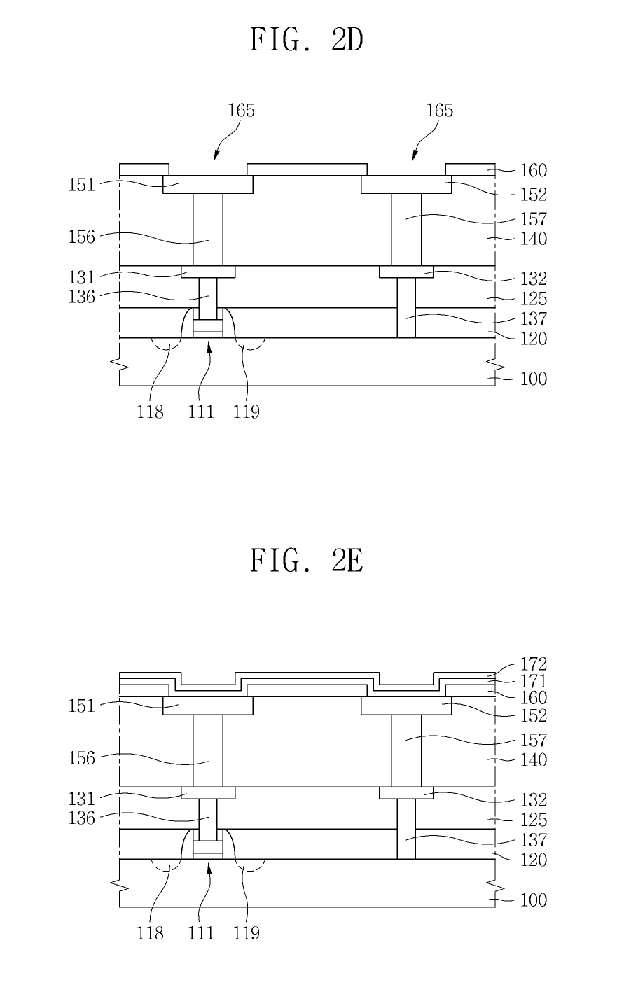

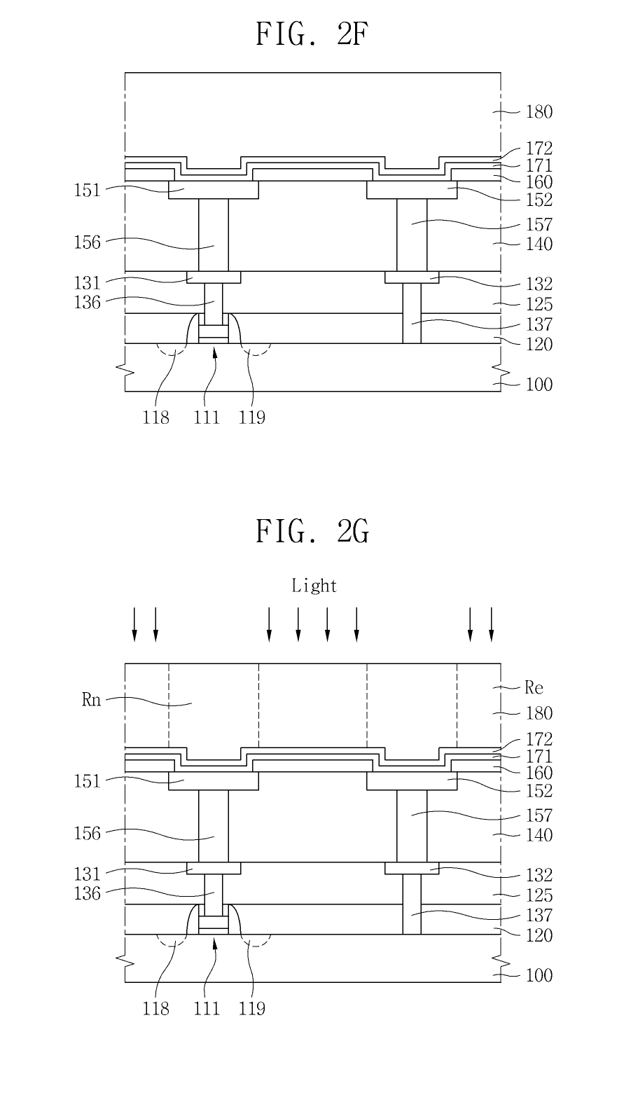

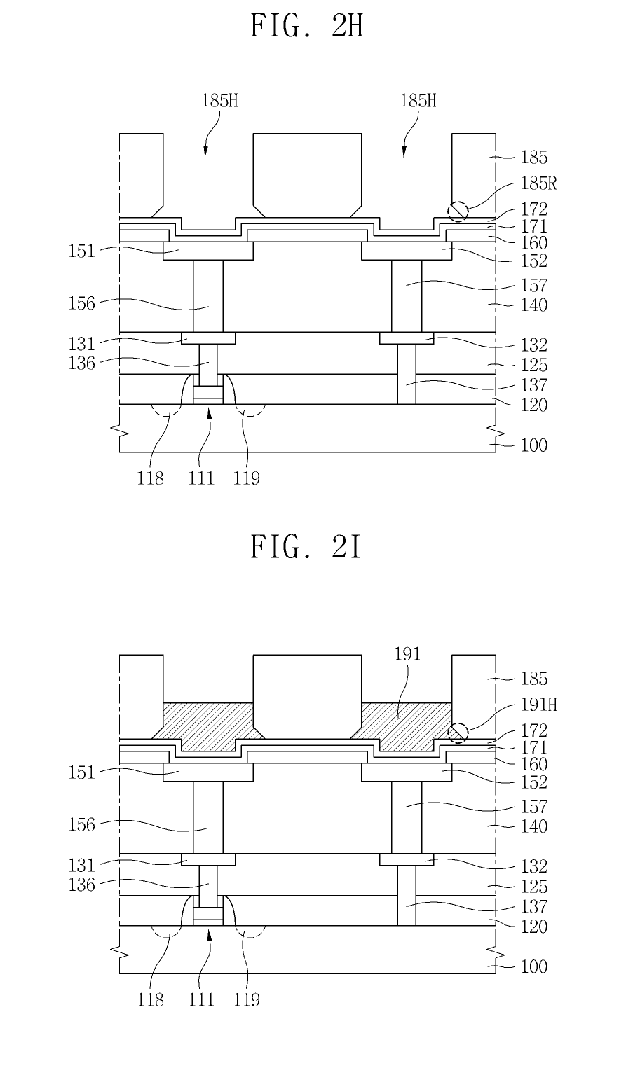

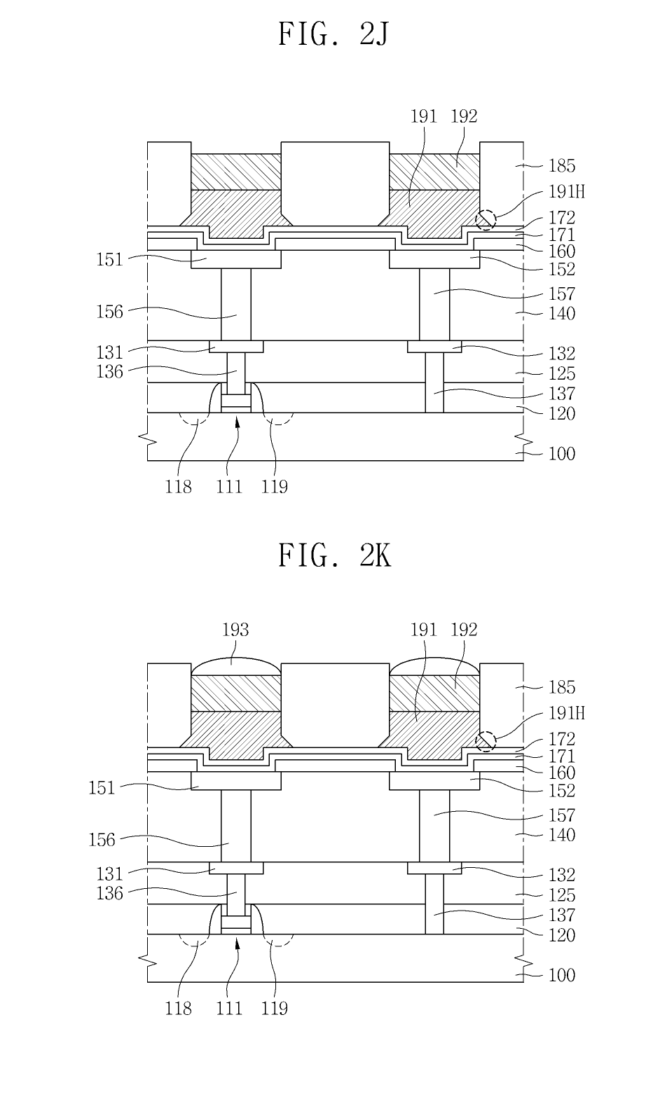

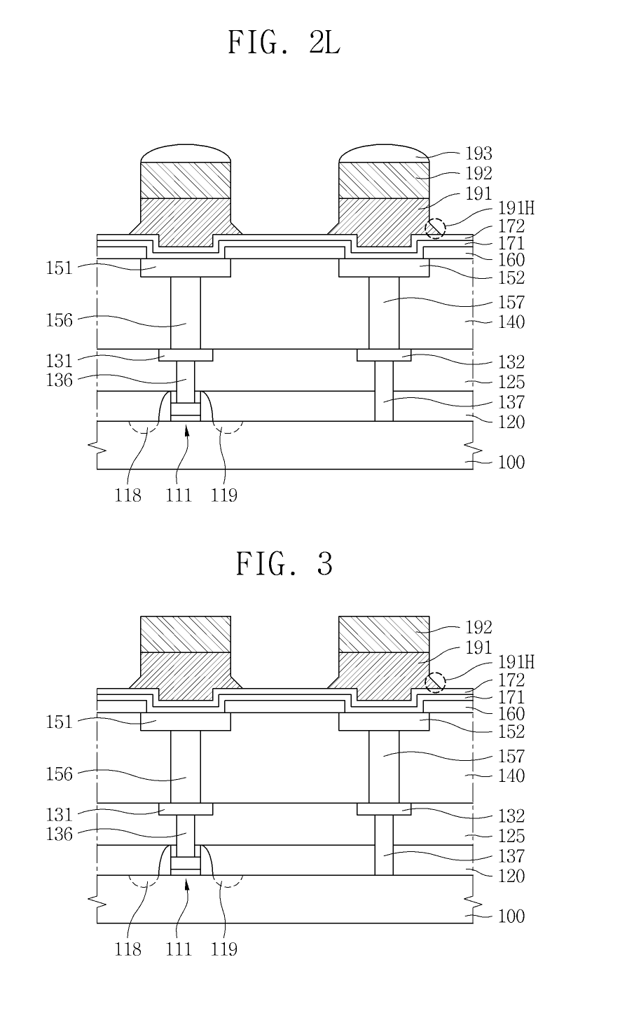

FIGS. 2A through 2L are schematic longitudinal sectional views illustrating a method of fabricating a semiconductor device according to embodiments of the disclosed subject matter.

Referring to FIG. 2A, the method of fabricating the semiconductor device according to the embodiments of the disclosed subject matter may include forming a transistor 110 on a substrate 100 and forming a lower interlayer insulating layer 120 to cover the transistor 110.

The substrate 100 may include a single crystalline silicon wafer, a silicon-on-insulator (SOI) wafer, a SiGe wafer, a SiC wafer, or a compound semiconductor wafer in which Group III elements (Al, Ga, and In) combine with Group V elements (O, As, and Sb).

The transistor 110 may include a gate pattern 111, a source region 118, and a drain region 119.

The gate pattern 111 may include a gate insulating layer 112, a gate electrode 113, a gate capping layer 114, and gate spacers 115. The gate insulating layer 112 may be formed directly on a surface of the substrate 100. The gate insulating layer 112 may be obtained by oxidizing the surface of the substrate 100. For example, the gate insulating layer 112 may include oxidized silicon, such as SiO₂, or an oxidized metal, such as HfO2 or Al₂O₃. The gate electrode 113 may include doped poly-Si, a metal silicide, and/or a metal, such as tungsten (W) or copper (Cu). The gate capping layer 114 and the gate spacers 115 may include an insulating material, such as silicon nitride, silicon oxide, or silicon oxynitride. The source region 118 and the drain region 119 may be formed by implanting an n-type dopant, such as phosphorus (P) or arsenic (As), or a p-type dopant, such as boron (B).

The lower interlayer insulating layer 120 may cover the transistor 110. For example, the lower interlayer insulating layer 120 may be in contact with the substrate 100 and the gate spacers 115, and a top surface of the lower interlayer insulating layer 120 and a top surface of the gate pattern 111 may be co-planar. The lower interlayer insulating layer 120 may include silicon oxide formed using a chemical vapor deposition (CVD) process.

Referring to FIG. 2B, the method may include forming an upper interlayer insulating layer 125 and lower metal lines 131 and 132 on the gate pattern 111 and the lower interlayer insulating layer 120. The upper interlayer insulating layer 125 may include silicon oxide. The lower metal lines 131 and 132 may be buried in an upper portion of the upper interlayer insulating layer 125. For example, top surfaces of the lower metal lines 131 and 132 and a top surface of the upper interlayer insulating layer 125 may be co-planar. The lower metal lines 131 and 132 may include a first lower metal line 131 electrically connected to the gate electrode 113 and a second lower metal line 132 electrically connected to the substrate 100.

The lower metal lines 131 and 132 may include a metal, such as tungsten or copper. The first lower metal line 131 may be electrically connected to the gate electrode 113 through the first lower via 136. For instance, the first lower via 136 may vertically penetrate the upper interlayer insulating layer 125 and the gate capping layer 114. The second lower metal line 132 may be electrically connected to the substrate 100 through the second lower via 137. For example, the second lower via 137 may vertically penetrate the upper interlayer insulating layer 125 and the lower interlayer insulating layer 120. The first lower via 136 and the second lower via 137 may include a metal, such as tungsten or copper. The lower metal lines 131 and 132 and the lower vias 136 and 137 may be formed using a dual damascene process.

Referring to FIG. 2C, the method may include forming an inter-metal insulating layer 140 and upper metal lines 151 and 152 on the upper interlayer insulating layer 125 and the lower metal patterns 131 and 132. The inter-metal insulating layer 140 may include silicon oxide. The upper metal lines 151 and 152 may be buried in an upper portion of the inter-metal insulating layer 140. For example, top surfaces of the upper metal lines 151 and 152 and a top surface of the inter-metal insulating layer 140 may be co-planar. The upper metal lines 151 and 152 may include a first upper metal line 151 electrically connected to the first lower metal line 131 and a second upper metal line 152 electrically connected to the second lower metal line 132. The upper metal lines 151 and 152 may include a metal, such as tungsten or copper.

The first upper metal line 151 may be electrically connected to the first lower metal line 131 through the first upper via 156, and the second upper metal line 152 may be electrically connected to the second lower metal line 132 through the second upper via 157. For example, the first upper via 156 and the second upper via 157 may vertically penetrate the inter-metal insulating layer 140. The first upper via 156 and the second upper via 167 may include a metal, such as tungsten or copper. The upper metal lines 151 and 152 and the upper vias 156 and 157 may be formed using a dual damascene process.

Referring to FIG. 2D, the method may include forming a passivation layer 160 to cover the inter-metal insulating layer 140 and the upper metal lines 151 and 152 and forming openings 165 to selectively and partially expose portions of top surfaces of the upper metal lines 151 and 152. The passivation layer 160 may include silicon nitride or polyimide (PI). The openings 165 may be formed using photolithography and etching processes.

Referring to FIG. 2E, the method may include conformally forming a bather metal layer 171 and a seed metal layer 172 on surfaces of the passivation layer 160 and the exposed surfaces of the upper metal lines 151 and 152. The barrier metal layer 171 may be formed using a CVD process. The barrier metal layer 171 may include a barrier metal, such as titanium (Ti), titanium nitride (TiN), tantalum (Ta), or tantalum nitride (TaN). The seed metal layer 172 may be formed on the barrier metal layer 171 using a physical vapor deposition (PVD) process, such as a sputtering process. The seed metal layer 172 may include a seed metal, such as copper (Cu), ruthenium (Ru), nickel (Ni), or tungsten (W).

Referring to FIG. 2F, the method may include forming a photoresist layer 180 on the seed metal layer 172 and performing a pre-exposure bake process. In the embodiments, it is assumed that the photoresist layer 180 is a negative type. Accordingly, the photoresist layer 180 may include a base resin having a cross-linking portion, a cross-linker, various additives, and a solvent.

If the photoresist layer 180 is a positive type, the photoresist layer 180 may include a base resin having acid-labile groups or acid protective groups, PAG (photo acid generator), various additives and a solvent. The additives may include a hydrophilic polymeric additive having a linear structural polymer containing both anion and cation. The hydrophilic polymeric additive may be distributed at lower portion of the photoresist layer 180 closer to the seed metal layer 172. The hydrophilic polymeric additive may be heavier than the base resin and/or the other additives. Accordingly, the hydrophilic polymeric additive has higher concentration at upper portion of the photoresist layer 180 and relatively lower concentration at lower portion of the photoresist layer 180 closer to the seed metal layer 172.

For example, the photoresist layer 180 may include a liquid or gel-type composition having viscosity. Accordingly, the photoresist layer 180 may be formed using a spin coating process. The pre-exposure bake process may include loading the substrate 100 coated with the photoresist layer 180 into a bake oven and applying heat to remove the solvent from the photoresist layer 180.

The solvent may contain various organic compounds. For example, the solvent may include at least one of pentane (CH₃—CH₂—CH₂—CH₂—CH₃, 36° C.), cyclopentane (C₅H₁₀, 40° C.), hexane (CH₃—CH₂—CH₂—CH₂—CH₂—CH₃, 69° C.), cyclohexane (C₆H₁₂, 81° C.), benzene (C₆H₆, 80° C.), toluene (C₆H₅—CH₃, 111° C.), 1,4-dioxane (—CH₂—CH₂—O—CH₂—CH₂—O—, 101° C.), chloroform (CHCl₃, 61° C.), diethyl ether (CH₃—CH₂—O—CH₂—CH₃, 35° C.), dichloromethane (DCM) (CH₂Cl₂, 40° C.), tetrahydrofuran (THF) (—CH₂—CH₂—O—CH₂—CH₂—, 66° C.), ethyl acetate (CH₃—C(═O)—O—CH₂—CH₃, 77° C.), acetone (CH₃—C(═O)—CH₃, 56° C.), dimethyl formamide (DMF) (H—C(═O)N(CH₃)₂, 153° C.), acetonitrile (MeCN) (CH₃—C≡N, 82° C.), dimethyl sulfoxide (DMSO) (CH₃—S(═O)—CH₃, 189° C.), propylene carbonate (C₄H₆O₃, 240° C.), formic acid (H—C(═O)OH, 101° C.), n-butanol (CH₃—CH₂—CH₂—CH₂—OH, 118° C.), isopropanol (IPA) (CH₃—CH(—OH)—CH₃, 82° C.), n-propanol (CH₃—CH(—OH)—CH₃, 97° C.), ethanol (CH₃—CH₂—OH, 79° C.), methanol (CH₃—OH, 65° C.), acetic acid (CH₃—C(═O)OH, 118° C.), nitromethane (CH₃—NO₂, 100 to 103° C.), and water (H—O—H, 100° C.). Temperatures in parentheses refer to boiling points. It is understood that the above are merely a few illustrative examples to which the disclosed subject matter is not limited.

The pre-exposure bake process may be performed at a temperature higher than a boiling point of the solvent contained in the photoresist layer 180 and lower than a glass transition temperature of the base resin. For example, assuming that the solvent has a boiling point of about 100° C. and the base resin has a glass transition temperature of about 150° C., the pre-exposure bake process may be performed at a temperature of about 100° C. to about 150° C. The pre-exposure bake process may remove almost an initial content or total content of the solvent in the photoresist layer 180. For instance, the pre-exposure bake process may include removing about 80 to 95% the initial content or total content of the solvent in the photoresist layer 180 and leaving about 5 to 20% the initial content or total content of the solvent in the photoresist layer 180. For example, assuming that when the photoresist layer 180 is laid in the bake oven maintained at a temperature higher than the boiling point of the solvent for a sufficient “removal time” or longer, at least about 99% the solvent is vaporized and removed, an pre-exposure bake process according to embodiments of the disclosed subject matter may be performed for a “residual time” shorter than the “removal time”. For example, the “residual time” may be about 75 to 95% the “removal time.” Assuming that the “removal time” is about 5 minutes (about 300 seconds), the “residual time” may be about 3 minutes and 45 seconds to 4 minutes and 45 seconds. In view of the fact that the solvent is removed by natural dryness, the “removal time” may be controlled to be shorter or longer. When the temperature of the pre-exposure bake process is reduced, the “removal time” may be increased, while the temperature of the pre-exposure bake process is raised, the “removal time” may be shortened. Accordingly, the temperature and duration time of the pre-exposure bake process may be appropriately controlled.

Referring to FIG. 2G, the method may include performing an exposure process. The exposure process may include selectively irradiating ultraviolet (UV) light to an exposure region Re of the photoresist layer 180 using a photolithography apparatus. For example, during the exposure process, a non-exposure region Rn vertically aligned with the upper metal lines 151 and 152 may not be irradiated with UV light, while exposure regions Re, which are not vertically aligned with the upper metal lines 151 and 152, may be exposed to UV light.

Referring to FIG. 2H, the method may include performing a post-exposure bake process and a developing process to form a photoresist pattern 185. The post-exposure bake process may include cross-linking the base resin with a cross-linking agent included in the photoresist layer 180 such that the base resin has a developing tolerance to a developer. The post-exposure bake process may include loading the substrate 100 into a bake oven and heating the substrate at a temperature lower than a glass transition temperature of the base resin of the photoresist layer 180. The post-exposure bake process may be performed at a temperature relatively near to the glass transition temperature of the base resin rather than to the boiling point of the organic solvent. That is, the post-exposure bake process may be performed at a higher temperature than the pre-exposure bake process.

The developing process may include removing the photoresist layer 180 from the non-exposure region Rn and forming the photoresist pattern 185 to leave the photoresist layer 180 on the exposure region Re. For example, the developing process may include supplying an alkali organic solvent such as TMAH (Tetramethyl Ammonium Hydroxide) onto the photoresist layer 180 to chemically dissolve and remove the photoresist layer 180 of the non-exposure region Rn.

When the photoresist layer 180 is the negative type, the photoresist layer 180 of the exposure region Re may form cross-links due to UV light, and may not dissolve in an organic solvent and remain to form the photoresist pattern 185.

When the photoresist layer 180 is the positive type, the hydrophilic polymeric additive may be changed into water (H₂O) by reacting the TMAH and removed. As the hydrophilic polymeric additive has a better reactivity than the base resion and the other additives, the hydrophilic polymeric additive and base resin therearound may be rapider and more removed than the base resin farther.

The photoresist pattern 185 may include bump holes 185H vertically aligned with the upper metal lines 151 and 152. The bump holes 185H may expose a top surface of the seed metal layer 172. Foot-shaped or tail-shaped side recesses 185R may be formed in lower portions of the bump holes 185H. In a top view, the side recesses 185R may surround the peripheries of the bump holes 185H in all directions. For example, when each of the bump holes 185H has a circular shape in the top view, each of the side recesses 185R may have a circular rim shape. Alternatively, when each of the bump holes 185H has a polygonal shape, each of the side recesses 185R may have a polygonal shape. The side recesses 185R may expose the seed metal layer 172, which may vertically overlap the photoresist pattern 185 under the photoresist pattern 185, to the air. Accordingly, a surface area of the seed metal layer 172 exposed in the top view may be greater than a sectional area of each of the bump holes 185H. As described above, the photoresist pattern 185 has the side recesses 185R since the hydrophilic polymeric additive has a better reactivity with the TMAH.

Referring to FIG. 2I, the method may include forming a lower plating layer 191 on the seed metal layer 172 using a first plating process to partially fill the bump holes 185H. The lower plating layer 191 may fill midway between top and bottom surfaces of the bump holes 185H. The lower plating layer 191 may have foot-shaped, tail-shaped, or rim-shaped hems 191H to fill the side recesses 185R. The hems 191H may protrude in a lateral direction to fill the side recesses 185R. Each of the hems 191H may have a flat bottom surface, an inclined top surface, and a sharp edge. For instance, the lower plating layer 191 may include nickel. When the lower plating layer 191 includes the same metal as the seed metal layer 172, an interface between the lower plating layer 191 and the seed metal layer 172 may disappear.

Referring to FIG. 2J, the method may include forming an upper plating layer 192 on the lower plating layer 191 using a second plating process to partially fill the bump holes 185H. The upper plating layer 192 may almost fill the bump holes 185H. The upper plating layer 192 may include copper.

Referring to FIG. 2K, the method may include forming a solder layer 193 on the upper plating layer 192 using a soldering process. The solder layer 193 may include tin (Sn) and silver (Ag).

Referring to FIG. 2L, the method may include removing the photoresist pattern 185. The removal of the photoresist pattern 185 may include performing a wet stripping process using sulfuric acid or an ashing process using O₂ plasma. The photoresist pattern 185 may be removed to expose top surfaces of the seed metal layer 172, which may not be vertically aligned with the upper metal lines 151 and 152.

Thereafter, referring to FIG. 1A, the method may include performing a wet etching process to remove the exposed seed metal layer 172 and the barrier metal layer 171 disposed under the exposed seed metal layer 172. During the wet etching process, the bump 190A including the barrier metal layer 171, the seed metal layer 172, the lower plating layer 191 having the hems 191H, the upper plating layer 192, and the solder layer 193 may be formed. For example, the removal of the exposed seed metal layer 172 may include performing a wet etching process using a chemical solution containing a hydrogen peroxide solution, citric acid, and water. The removal of the barrier metal layer 171 may include performing a wet etching process using a chemical solution containing a hydrogen peroxide solution, calcium hydroxide, and water.

During the wet etching process, undercuts Uc may be formed under the hems 191H. The hems 191H may reduce the removed amounts of the seed metal layer 172 exposed during the wet etching process and the barrier metal layer 171 disposed thereunder. That is, a lateral depth to which the undercuts Uc are formed may be reduced. A horizontal width of the seed metal layer 172 or the barrier metal layer 171 in which the undercuts Uc are formed may be greater than a horizontal width of the first plating layer 191 excluding the hems 191H. Accordingly, the influence of the undercuts Uc upon the supporting capability, mechanical stability, and physical durability of the bumps 190 may be reduced. According to the disclosed subject matter, the hems 191H may minimize the influence of the undercuts Uc upon lower portions of pad patterns.

FIG. 3 is a schematic longitudinal sectional view illustrating a method of fabricating a semiconductor device according to embodiments of the disclosed subject matter. Referring to FIG. 3, the method of fabricating the semiconductor device according to the embodiments of the disclosed subject matter may include performing the processes described with reference to FIGS. 2A through 2J and removing the photoresist pattern 185 of FIG. 2J. For example, the process of forming the solder layer 193 as described with reference to FIG. 2K may be omitted. Subsequently, the method may include removing the exposed seed metal layer 172 and the barrier metal layer 171 disposed thereunder with reference to FIG. 1B.

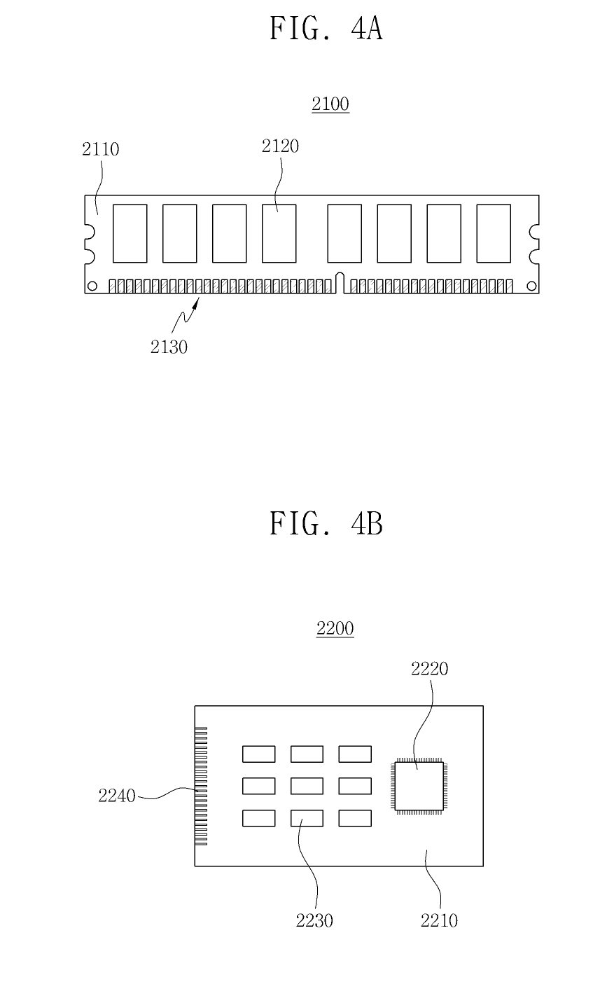

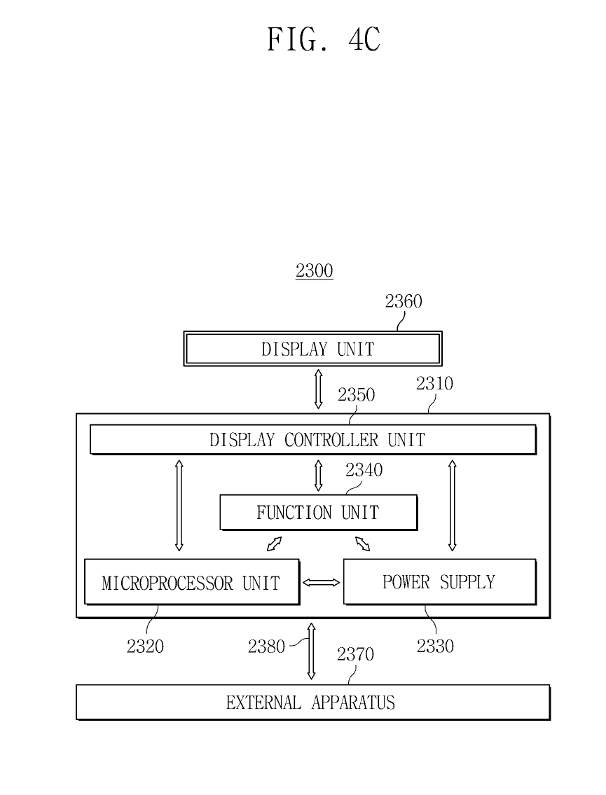

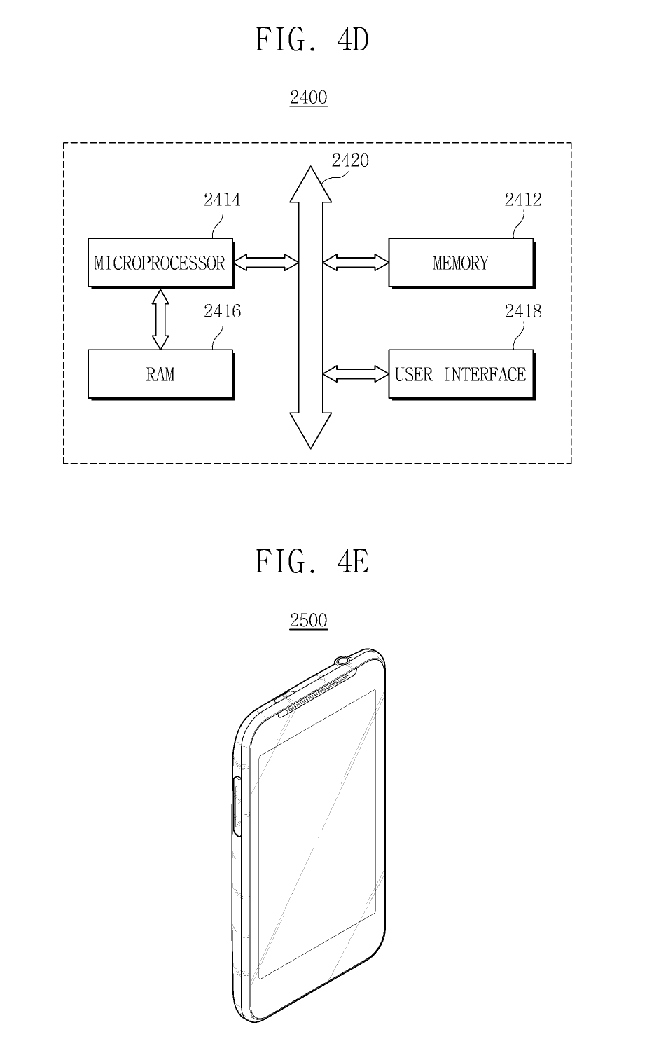

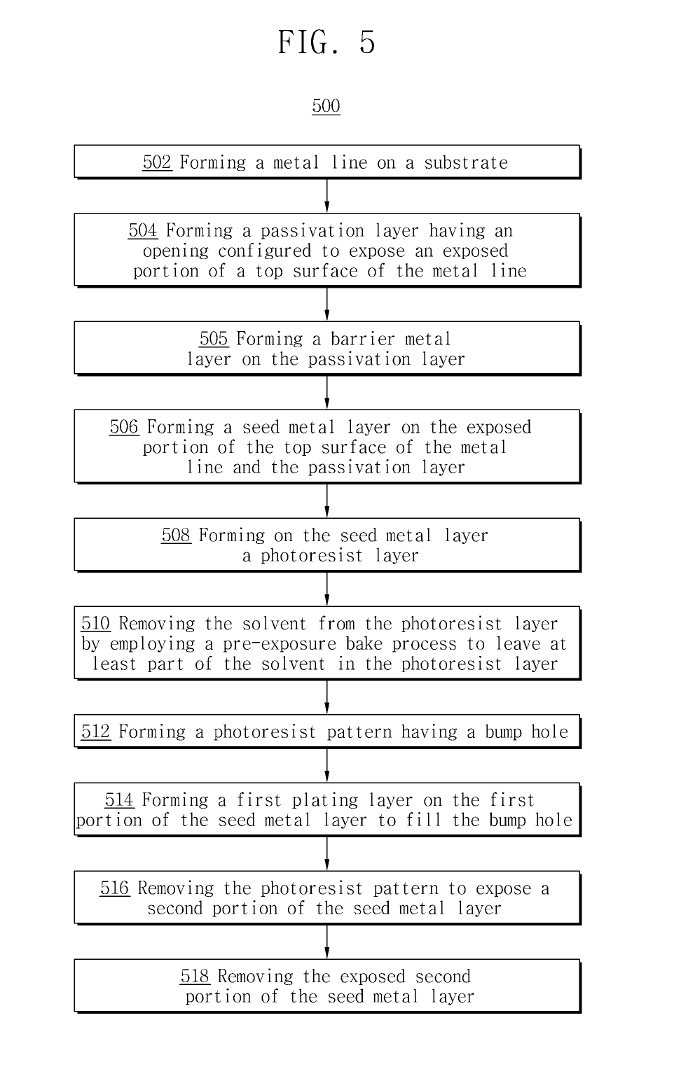

FIG. 4A is a conceptual diagram of a memory module 2100 including at least one of the semiconductor devices 10A to 10D having bumps according to various embodiments of the disclosed subject matter. Referring to FIG. 4A, the memory module 2100 may include a memory module substrate 2110, and a plurality of memory devices 2120 and a plurality of terminals 2130, which may be disposed on the memory module substrate 2110. The memory module substrate 2110 may include a printed circuit board (PCB) or a wafer. The memory devices 2120 may include at least one of the semiconductor devices 10A to 10D having bumps according to various embodiments of the disclosed subject matter, or a semiconductor package including the at least one of the semiconductor devices 10A to 10D having the bumps. The plurality of terminals 2130 may include a conductive metal. The terminals 2130 may be electrically connected to the memory devices 2120, respectively. Since the memory module 2100 includes at least one of the semiconductor devices 10A to 10D having bumps with fine, mechanical, and physical properties, the performance of the memory module 2100 may be improved.

FIG. 4B is a conceptual diagram of a memory card 2200 including at least one of semiconductor devices 10A to 10D having bumps according to various embodiments of the disclosed subject matter. Referring to FIG. 4B, the memory card 2200 according to embodiments of the disclosed subject matter may include at least one of semiconductor devices having bumps according to various embodiments of the disclosed subject matter, which may be mounted on a memory card substrate 2210. The memory card 2200 may further include a microprocessor (MP) 2220 mounted on the memory card substrate 2210. Input/output (I/O) terminals 2240 may be disposed on at least one side of the memory card substrate 2210.

FIG. 4C is a conceptual block diagram of an electronic system 2300 including at least one of the semiconductor devices 10A to 10D having bumps according to various embodiments of the disclosed subject matter. Referring to FIG. 4C, at least one of semiconductor devices having bumps according to various embodiments of the disclosed subject matter may be included in the electronic system 2300. The electronic system 2300 may include a body 2310. The body 2310 may include an MP unit 2320, a power supply 2330, a function unit 2340, and/or a display controller unit 2350. The body 2310 may be a system board or mother board having a PCB. The MP unit 2320, the power supply 2330, the function unit 2340, and the display controller unit 2350 may be mounted on the body 2310. A display unit 2360 may be disposed on a top surface of the body 2310 or outside the body 2310. For example, the display unit 2360 may be disposed on a surface of the body 2310 and display an image processed by the display controller unit 2350. The power supply 2330 may receive a predetermined voltage from an external power source, divide the predetermined voltage into various voltage levels, and transmit divided voltages to the MP unit 2320, the function unit 2340, and the display controller unit 2350. The MP unit 2320 may receive a voltage from the power supply 2330 and control the function unit 2340 and the display unit 2360. The function unit 2340 may implement various functions of the electronic system 2300. For instance, when the electronic system 2300 is a mobile electronic product, such as a portable phone, the function unit 2340 may include several elements capable of wireless communication functions, such as output of an image to the display unit 2360 or output of a voice to a speaker, by dialing or communication with an external apparatus 2370. When the function unit 2340 includes a camera, the function unit 2340 may serve as an image processor. In other embodiments, when the electronic system 2300 is connected to a memory card to increase capacity, the function unit 2340 may be a memory card controller. The function unit 2340 may exchange signals with the external apparatus 2370 through a wired or wireless communication unit 2380. In addition, when the electronic system 2300 needs a universal serial bus (USB) to expand functions thereof, the function unit 2340 may serve as an interface controller. At least one of the semiconductor devices 10A to 10D having bumps according to various embodiments of the disclosed subject matter may be included in at least one of the MP unit 2320 and the function unit 2340.

FIG. 4D is a schematic block diagram of another electronic system 2400 including at least one of semiconductor devices 10A to 10D having bumps according to embodiments of the disclosed subject matter. Referring to FIG. 4D, the electronic system 2400 may include at least one of semiconductor devices 10A to 10D having bumps according to various embodiments of the disclosed subject matter. The electronic system 2400 may be used to fabricate a mobile device or computer. For example, the electronic system 2400 may include a memory system 2412, an MP 2414, a random access memory (RAM) 2416, and a user interface 2418, which may perform data communication using a bus 2420. The MP 2414 may program and control the electronic system 2400. The RAM 2416 may be used as an operation memory of the MP 2414. For example, the MP 2414 or the RAM 2416 may include at least one of the semiconductor devices 10A to 10D having bumps according to embodiments of the disclosed subject matter. The MP 2414, the RAM 2416, and/or other elements may be assembled within a single package. The user interface 2418 may be used to input data to the electronic system 2400 or output data from the electronic system 2400. The memory system 2412 may store codes for operating the MP 2414, data processed by the MP 2414, or external input data. The memory system 2412 may include a controller and a memory.

FIG. 4E is a schematic diagram of a mobile wireless device 2500 including at least one of the semiconductor devices 10A to 10D having bumps according to various embodiments of the disclosed subject matter. The mobile wireless device 2500 may be interpreted as a tablet personal computer (PC). Furthermore, at least one of the semiconductor devices 10A to 10D according to various embodiments of the disclosed subject matter may be used not only for a tablet PC but also for a portable computer such as a laptop computer, an MPEG-1 audio layer 3 (MP3) player, an MP4 player, a navigation device, a solid-state disk (SSD), a desktop computer, or electronic devices for automotive and household uses.

A semiconductor device according to various embodiments of the disclosed subject matter can include bumps upon which the influence of undercuts can be reduced. Accordingly, the mechanical and physical stability of the bumps can be improved, and the electrical performance, mechanical intensity, physical durability, and lifespan of the semiconductor device can be enhanced.

FIG. 5 is a flow chart of an example embodiment of a technique 500 in accordance with the disclosed subject matter. In various embodiments, the technique 500 may be used or produced by the systems such as those of FIGS. 1A, 1B, 1C, and 1D. Furthermore, portions of technique 500 may be used with or produce the systems such as that of FIGS. 2A, 2B, 2C, 2D, 2E, 2F, 2G, 2H, 2I, 2J, 2K, and 2L. Although, it is understood that the above are merely a few illustrative examples to which the disclosed subject matter is not limited. It is understood that the disclosed subject matter is not limited to the ordering of or number of actions illustrated by technique 500.

Block 502 illustrates that, in one embodiment, a metal line may be formed on a substrate, as described above. In one embodiment, forming the metal line may include forming an inter-metal insulating layer on the substrate, and forming the metal line within the inter-metal insulating layer, as described above. In such an embodiment, a top surface of the inter-metal insulating layer and a top surface of the metal line may be co-planar, as described above.

Block 504 illustrates that, in one embodiment, a passivation layer may be formed on the substrate, as described above. In such an embodiment, the passivation layer may include an opening configured to, at least partially, expose an exposed portion of a top surface of the metal line, as described above. Block 505 illustrates that, in one embodiment, a barrier metal layer may be formed on the passivation layer, as described above. Block 506 illustrates that, in one embodiment, a seed metal layer may be formed on the exposed portion of the top surface of the metal line and the passivation layer, as described above. In some embodiments, the barrier metal layer may be formed between the metal line and the seed metal layer, as described above.

Block 508 illustrates that, in one embodiment, a photoresist layer may be formed on the seed metal layer, as described above. In one embodiment, the photoresist layer may include a solvent, as described above. In another embodiment, the photoresist layer may include a base resin, a cross-linking agent, as described above.

Block 510 illustrates that, in one embodiment, the solvent may be removed, at least in part, from the photoresist layer, as described above. In one embodiment, this may include employing a pre-exposure bake process to leave at least part of the solvent in the photoresist layer, as described above. In various embodiments, a majority of the solvent may be removed, as described above. In one embodiment, removing the solvent from the photoresist layer may include performing the pre-exposure bake process at a temperature higher than a boiling point of the solvent, as described above. In another embodiment, removing the solvent from the photoresist layer may include performing the pre-exposure bake process at a temperature lower than a glass transition temperature of the base resin, as described above. In yet another embodiment, removing the solvent from the photoresist layer may include removing between 80 to 95%, inclusive, of an initial content of the solvent from the photoresist layer, as described above. In some embodiments, removing the solvent from the photoresist layer may include performing the pre-exposure bake process for a time duration substantially equivalent to about 75 to 95% a time duration estimated to be required in order to remove at least 99% the solvent from the photoresist layer, as described above.

Block 512 illustrates that, in one embodiment, a photoresist pattern may be formed, as described above. In some embodiments, the photoresist pattern may be converted from the photoresist layer, as described above. In various embodiments, the photoresist pattern may include a bump hole that exposes a first portion of the seed metal layer, as described above. In some embodiments, the bump hole may include a side recess formed by removing the photoresist pattern outward from a side surface of the bump hole in a longitudinal sectional view, as described above. In one embodiment, the side recess may partially expose a surface of the seed metal layer that is vertically aligned with and overlaps the photoresist pattern, as described above.

Block 514 illustrates that, in one embodiment, a first plating layer may be formed by employing a first plating process on the first portion of the seed metal layer to fill the bump hole, as described above. In such an embodiment, the first plating layer may include a hem filling, at least partially, the side recess, as described above. In one embodiment, the hem may include a rim shape to surround a periphery of the first plating layer, as described above. In another embodiment, the hem may include a horizontally flat bottom surface, an inclined top surface, and a sharp edge, as described above.

Block 516 illustrates that, in one embodiment, the photoresist pattern may be removed to expose a second portion of the seed metal layer, as described above. Block 518 illustrates that, in one embodiment, the exposed second portion of the seed metal layer may be removed, as described above. In one embodiment, removing the seed metal layer may include forming an undercut under the hem, as described above. In various embodiments, a horizontal width of the seed metal layer in which the undercut is formed may be greater than a horizontal width of the first plating layer excluding the hem, as described above.

In another embodiment, a second plating layer may be formed on the first plating layer using a second plating process, as described above. In some such embodiments, the first plating layer may include nickel, and the second plating layer may include copper, as described above. In yet another embodiment, a solder layer may be formed on the second plating layer using a soldering process, as described above.

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to be included within the scope of this disclosed subject matter as defined in the claims. In the claims, means-plus-function clauses are intended to cover the structures described herein as performing the recited function, and not only structural equivalents but also equivalent structures.

1. A method of fabricating a semiconductor device, comprising:
forming a metal line on a substrate;
forming a passivation layer having an opening configured to, at least partially, expose an exposed portion of a top surface of the metal line;
forming a seed metal layer on the exposed portion of the top surface of the metal line and the passivation layer;
forming, on the seed metal layer, a photoresist layer including a base resin, a cross-linking agent, and a solvent;
removing the solvent from the photoresist layer by employing a pre-exposure bake process to leave at least part of the solvent in the photoresist layer;
forming a photoresist pattern having a bump hole that exposes a first portion of the seed metal layer, wherein the bump hole includes a side recess formed by removing the photoresist pattern outward from a side surface of the bump hole in a longitudinal sectional view;
forming a first plating layer by employing a first plating process on the first portion of the seed metal layer to fill the bump hole, the first plating layer having a hem filling, at least partially, the side recess;
removing the photoresist pattern to expose a second portion of the seed metal layer; and
removing the exposed second portion of the seed metal layer,
wherein removing the seed metal layer includes forming an undercut under the hem.

2. The method of claim 1, further comprising forming a barrier metal between the metal line and the seed metal layer.

3. The method of claim 1, wherein removing the solvent from the photoresist layer includes performing the pre-exposure bake process at a temperature higher than a boiling point of the solvent.

4. The method of claim 1, wherein removing the solvent from the photoresist layer includes performing the pre-exposure bake process at a temperature lower than a glass transition temperature of the base resin.

5. The method of claim 1, wherein removing the solvent from the photoresist layer includes removing between 80 to 95%, inclusive, of an initial content of the solvent from the photoresist layer.

6. The method of claim 1, wherein removing the solvent from the photoresist layer includes performing the pre-exposure bake process for a time duration substantially equivalent to about 75 to 95% a time duration estimated to be required in order to remove at least 99% the solvent from the photoresist layer.

7. The method of claim 1, wherein the side recess partially exposes a surface of the seed metal layer that is vertically aligned with and overlaps the photoresist pattern.

8. The method of claim 1, wherein a horizontal width of the seed metal layer in which the undercut is formed is greater than a horizontal width of the first plating layer excluding the hem.

9. The method of claim 1, wherein the hem includes a rim shape to surround a periphery of the first plating layer.

10. The method of claim 9, wherein the hem includes a horizontally flat bottom surface, an inclined top surface, and a sharp edge.

11. The method of claim 1, further comprising forming a second plating layer on the first plating layer using a second plating process.

12. The method of claim 11, further comprising forming a solder layer on the second plating layer using a soldering process.

13. The method of claim 11, wherein the first plating layer includes nickel, and the second plating layer includes copper.

14. The method of claim 1, wherein the forming of the metal line comprises:
forming an inter-metal insulating layer on the substrate; and
forming the metal line within the inter-metal insulating layer,
wherein a top surface of the inter-metal insulating layer and a top surface of the metal line are substantially co-planar.

15. A method of fabricating a semiconductor device, the method comprising:
forming a passivation layer on a substrate;
forming a barrier metal layer on the passivation layer;
forming a seed metal layer on the barrier metal layer;
forming a photoresist layer, wherein the photoresist layer includes an organic solvent on the seed metal layer;
removing at least 50% of the organic solvent from the photoresist layer;
converting the photoresist layer into a photoresist pattern, the photoresist pattern having a bump hole that includes a substantially vertical sidewall to expose a portion of a top surface of the seed metal layer; and
forming a plating layer on the exposed top surface of the seed metal layer to, at least partially, fill the bump hole,
wherein the bump hole has a side recess partially exposing the top surface of the seed metal layer in a lower portion of the photoresist pattern, and
wherein the plating layer includes a protruding hem to fill the side recess.

16-20. (canceled)

21. A method of fabricating a semiconductor device, comprising:
forming a metal line on a substrate;
forming a passivation layer having an opening exposing a portion of a top surface of the metal line;
forming a seed metal layer on the portion of the top surface of the metal line and the passivation layer;
forming a photoresist layer on the seed metal layer, the photoresist layer including a base resin, a protective group, photo-acid generator, a hydrophilic polymeric additive, and a solvent;
forming a photoresist pattern having a bump hole that exposes a first portion of the seed metal layer, wherein the bump hole includes a side recess formed by removing the photoresist pattern outward from a side surface of the bump hole in a longitudinal sectional view;
forming a plating layer by employing a plating process on the first portion of the seed metal layer to fill the bump hole, the plating layer having a hem filling the side recess;
removing the photoresist pattern to expose a second portion of the seed metal layer; and
removing the second portion of the seed metal layer,
wherein removing the seed metal layer includes forming an undercut under the hem.

22. The method of claim 21, wherein the hydrophilic polymeric additive has a linear structure comprising anion and cation.

23. The method of claim 22, wherein the hydrophilic polymeric additive has relatively higher concentration at upper portion of the photoresist layer and relatively lower concentration at lower portion of the photoresist layer closer to the seed metal layer.

24. The method of claim 23, wherein forming the photoresist pattern comprises developing the photoresist layer using TMAH (Tetramethyl Ammounium Hydroxide).

25. The method of claim 24, wherein the hydrophilic polymeric additive has a better reactivity than the base resin with the TMAH.
